(19) United States
(12) Patent Application Publication
(10) Pub. No.: US 2026/0244107 A1
(43) Pub. Date: Aug. 20, 2026

(54) SYSTEM AND METHODS OF LITHOGRAPHIC EXPOSURE TO IMPROVE ETCH PERFORMANCE AND YIELD

(71) Applicant: Tokyo Electron Limited, Tokyo (JP)

(72) Inventors: Anton DEVILLIERS, Albany, NY (US); Hoyoung KANG, Albany, NY (US)

(21) Appl. No.: 19/541,338

(22) Filed: Feb. 16, 2026

Related U.S. Application Data
(60) Provisional application No. 63/759,345, filed on Feb. 17, 2025.

(51) Int. Cl. G03F 7/20; G03F 7/00

(52) U.S. Cl. CPC G03F 7/2028; G03F 7/70466

(57) ABSTRACT

Techniques herein include methods and systems of processing a wafer for semiconductor fabrication. Methods include a two-stage process of exposure of die locations using two different exposure systems. A first exposure system is used to expose die patterns that are laid out to be positioned fully within a wafer perimeter, while a second exposure system is used to expose edge die regions in which die pattern locations extend beyond the wafer perimeter. The second exposure system is selected to have a lithographic exposure resolution less than that of the first exposure system. When applied to EUV lithographic exposure, EUV systems are used to expose patterns within the wafer perimeter, while UV or DUV systems are used to expose patterns or fields extending beyond the wafer perimeter, resulting in relief patterns enabling uniform etch results without exposing the entire wafer surface area using the first exposure system.

### CROSS REFERENCE TO RELATED APPLICATIONS

The present disclosure claims the benefit of U.S. Provisional Patent Application No. 63/759,345, filed on Feb. 17, 2025, entitled “System and Methods of Lithographic Exposure to Improve Etch Performance and Yield,” which is incorporated herein by reference in its entirety.

### BACKGROUND OF THE INVENTION

This disclosure relates generally to methods of microfabrication, and more specifically to photolithography.

Semiconductor fabrication involves multiple varied processes. One primary fabrication process is known as photolithography (also called microlithography). Photolithography uses patterned radiation, such as ultraviolet or visible light, to generate microscopic patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

Exposure systems (also called exposure tools) are used to implement photolithographic techniques. An exposure system typically includes an illumination system, a reticle (also called a photomask) or spatial light modulator (SLM) for creating a circuit pattern, a projection system, and a wafer alignment stage for aligning a semiconductor wafer coated with photosensitive resist (photoresist). The illumination system illuminates a region of the reticle or SLM with a (preferably) rectangular slot illumination field. The projection system projects an image of the illuminated region of the reticle pattern onto the wafer. This creates a latent pattern, in the layer of photoresist, that can be developed resulting in a relief pattern or topographic pattern, which is useful as an etch mask to transfer patterns into underlying layers of material on the semiconductor wafer.

### SUMMARY

Lithography tools vary in complexity and cost. Regarding cost, there is a cost for the tool itself, as well as for the operation of the tool. Generally, lithography tools with smaller printing resolution cost more to acquire and operate. For example, a 193 nm scanner tool costs more to operate than an I-line tool. Likewise, an EUV (extreme ultraviolet) lithography tool costs more to operate than a 193 nm tool. With EUV lithography tools in particular, minimizing scans or prints can provide significant cost and time benefits.

Microfabrication of integrated circuits typically includes printing circuit patterns on a wafer to create dies. Dies are typically rectangular in shape, while wafers are circular. As can be appreciated, laying out rectangular dies within a circular wafer means that not all surface area available on the wafer can be used to fabricate dies. This is apparent along the periphery of the wafer where rectangular corners of dies meet the circular edge of the wafer and extend beyond the wafer perimeter.

In areas along the edge of the wafer that can only fit a portion of a die—meaning that a die in that region would be nonfunctional—it might seem logical to omit exposing these edge areas to patterned lithography to reduce operation cost of expensive exposures. These edge regions of partial dies, however, need to be exposed to the circuit pattern for subsequent uniform etching. Omitting exposure in these edge regions reduces yield of chips because it causes uneven plasma etching in subsequent pattern transfer steps. This is because the etch uniformity of plasmas formed over wafers is, in part, a function of relief pattern density. Regions with dissimilar relief topology cause nonuniformities in the plasma. Accordingly, these partial die areas need to be exposed to the circuit pattern so that the wafer has a uniform relief pattern for better yield from etch processing. Otherwise, dies within the wafer perimeter can become nonfunctional due to nonuniform pattern transfer. Thus, the conventional process is exposing an entire wafer surface to the die pattern, even when the die pattern extends beyond the wafer perimeter. With lower resolution lithography systems, exposing the additional edge areas with the circuit pattern was not an excessive additional cost. With advanced lithography systems, however, such as EUV, the partial die exposures add a substantial cost to EUV lithography system operation.

Techniques herein include methods and systems for maintaining etch transfer yield while reducing cost and time of lithographic exposures. Such techniques include a secondary patterning exposure for the partial die regions along a wafer perimeter using a lesser-resolution exposure that matches a pattern density from the primary (greater-resolution) exposure of dies fully within the wafer perimeter. This secondary patterning exposure can include using a direct-write tool or other mask-based exposure. This secondary exposure can have a lower resolution, and a pattern that does not need to be electrically valid, but a pattern that has features (lines and shapes) that match or approximate a shape density (shape density or coverage density) of the primary pattern. The result is that wafers processed accordingly herein can be etched for pattern transfer at high yield rates, but with a lower wafer cost and lower processing time because expensive EUV or DUV exposures were not completed on the partial die locations.

One embodiment includes a method of processing a wafer. The method includes identifying a wafer and an exposure layout to be applied to the wafer using a first photolithography system. The exposure layout includes exposure fields for lithographic exposure using a photomask. Each exposure field includes one or more die patterns. The wafer has a wafer perimeter defining a working surface for receiving lithographic exposure patterns. The method includes identifying, from the exposure layout, first exposure fields that are positioned fully within the wafer perimeter, second exposure fields that are positioned partially within the wafer perimeter and that include at least one complete die pattern positioned within the wafer perimeter, and third exposure fields that are positioned partially within the wafer perimeter and that do not include at least one complete die pattern positioned within the wafer perimeter. The method includes receiving the wafer before or after the first photolithography system has executed a first photolithographic exposure that exposes the first exposure fields and the second exposure fields to a first pattern of actinic radiation resulting in a first latent pattern formed in a layer of photoresist deposited on the wafer within the first exposure fields and the second exposure fields, while the third exposure fields are not exposed by the first photolithography system. The method includes executing a second photolithographic exposure that exposes the third exposure fields to a second pattern of actinic radiation using a second photolithography system resulting in a second latent pattern formed in the layer of photoresist within the third exposure fields, the second pattern of actinic radiation having a comparatively lesser resolution compared to the first pattern of actinic radiation, a pattern density of the second pattern of actinic radiation matching a pattern density of the first pattern of actinic radiation.

Embodiments also include a coater-developer system for processing a semiconductor wafer. The system includes an equipment front-end module having a mechanism for loading and unloading one or more wafers to be processed. The system includes a wafer processing region having multiple wafer processing modules including modules configured for coating wafers via spin-on deposition, modules configured for baking wafers, and modules configured for developing exposed wafers. The system includes a tool interface module defining a region to physically connect the coater-developer tool to a photolithographic exposure tool for exposure of circuit patterns using EUV lithography, the tool interface module configured to collect and store a queue of wafers for transfer to, and reception from, the photolithographic exposure tool. The system includes a robotic wafer transport system configured to move wafers from the equipment front-end module to wafer processing regions, configured to move wafers among wafer processing modules in the wafer process region, and configured to move wafers from the wafer processing region to the tool interface module. The system includes an edge die exposure module positioned within the tool interface module, the edge die exposure module including a DUV exposure system having optics and a pattern generation mechanism to expose edge die regions with a pattern of actinic radiation that has a pattern density matching a pattern density of an EUV pattern of radiation corresponding to dies fully on a working surface of the wafer, the edge die regions including dies that are partially on the working surface of the wafer and extend beyond a wafer perimeter.

Of course, the order of discussion of the different steps described herein has been presented for clarity's sake. In general, these steps can be performed in any suitable order. Additionally, although each of the different features, techniques, configurations, et cetera, herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIG. 1 depicts an exposure layout of an example wafer.

FIG. 2 depicts an exposure layout of an example wafer.

FIG. 3 depicts an exposure layout of an example wafer.

FIGS. 4A, 4B, and 4C depict example exposure field layouts.

FIGS. 5A and 5B illustrate detailed exposure field processing herein.

FIGS. 6A and 6B illustrate secondary wafer exposure herein.

FIGS. 7A and 7B illustrate secondary wafer exposure herein.

FIG. 8 illustrates an example exposure system configuration herein.

FIG. 9 illustrates an example exposure system configuration herein.

FIG. 10 illustrates an example exposure system configuration herein.

FIG. 11 illustrates an example reticle design herein.

FIG. 12 shows a reticle map corresponding to the example reticle design.

FIG. 13 is a top view of an example exposure module herein.

FIG. 14 is a side view of an example exposure module herein.

FIG. 15 is a layout of an example exposure system herein.

FIG. 16 is a perspective view of an example exposure system herein.

FIG. 17 is a layout of an example exposure system herein.

FIG. 18 is a layout of an example exposure system herein.

FIG. 19 is a flow chart of an example method herein.

### DETAILED DESCRIPTION

Techniques herein include methods and systems for maintaining etch transfer yield while reducing cost and time of lithographic exposures. Such techniques include a secondary patterning exposure for partial die regions along a wafer perimeter using a lesser-resolution exposure that matches a pattern density from the primary (greater-resolution) exposure of dies fully within the wafer perimeter. This secondary patterning exposure can include using a direct-write tool or other mask-based exposure system or module. This secondary exposure can have a lower resolution, and a pattern that does not need to be electrically valid, but a pattern that has features (lines and shapes) that match or approximate a shape density of the primary pattern. The result is that wafers processed accordingly can be etched for pattern transfer at high yield rates, but with a lower wafer cost and lower processing time because expensive EUV or DUV exposures were not completed on the partial die locations.

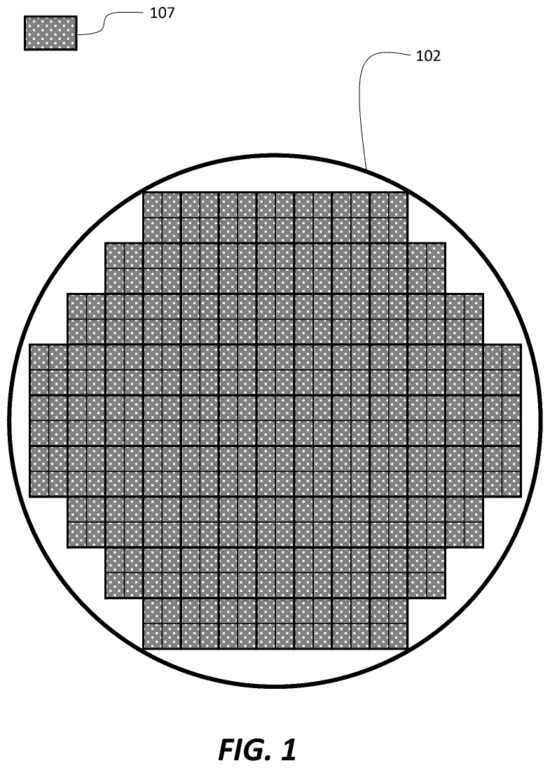

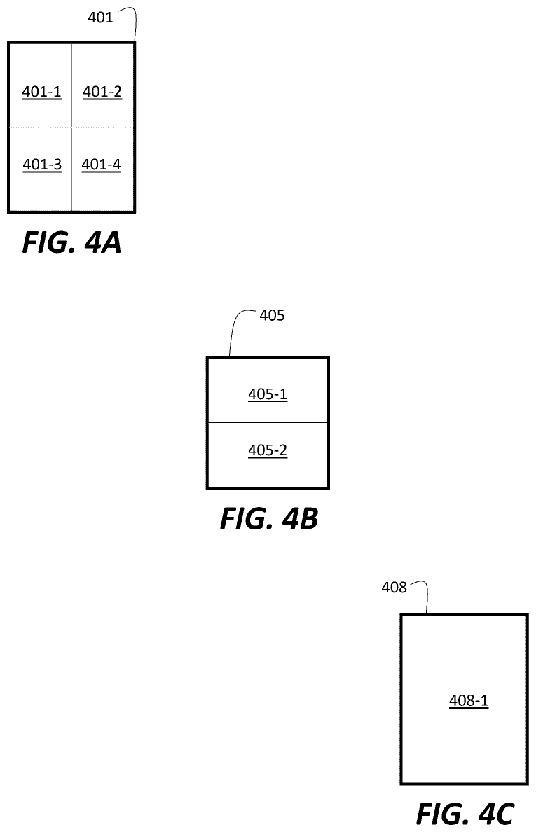

Referring now to FIG. 1, a wafer 102 is illustrated with a die layout. Depicted within the circle (wafer 102) is a layout of exposure fields and dies. In photolithography, a given exposure field can vary in size from one scanner to another, and from one wavelength to another. FIG. 4A illustrates an example exposure field 401 that includes dies 404-1, 401-2, 401-3, and 401-4. Thus, four dies fit within exposure field 401. FIG. 4B illustrates exposure field 405 that includes two dies (die 405-1 and 405-2). FIG. 4C illustrates exposure field 408 that includes a single die 408-1. Note that die 408-1 could represent a whole die or a part of a die such as one half of a die. In some integrated circuit fabrication techniques, dies can be larger than a given exposure field and so die components are separately exposed and then combined or “stitched” together along an edge. The example of FIG. 1 depicts exposure fields 107 having four dies each and shown with a particular hatch pattern for identification. What is illustrated in FIG. 1 is all the exposure fields that can be fit within wafer 102. That is, all the exposure fields positioned completely within the perimeter of wafer 102. All of these dies have a chance at being a functional circuit.

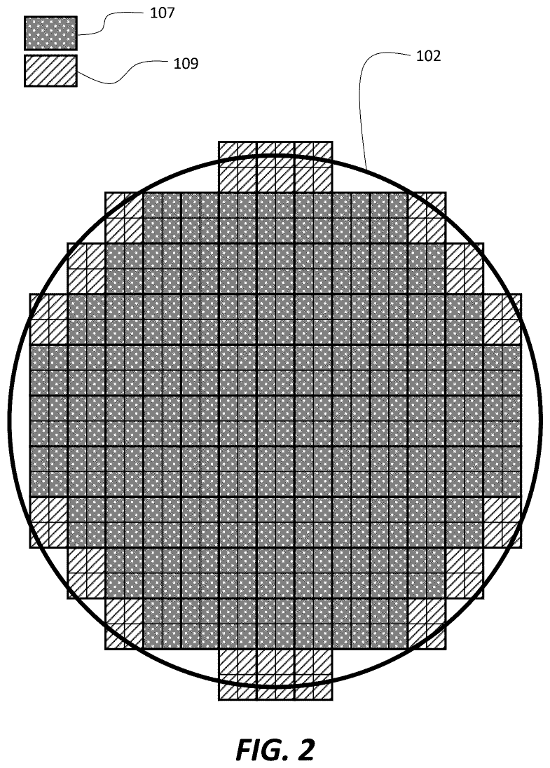

FIG. 2 shows the same layout of FIG. 1, but with added exposure field 109 and a corresponding hatch pattern. These added fields are partial exposure fields, or exposure fields that, as laid out, extend beyond a perimeter of wafer 102, but that have at least one of four dies that fall within the wafer perimeter. These partial exposure fields have a potential yield of 25% to 75% of the dies, and thus are worth a full exposure of a primary exposure patten. Of course, some of the exposure is wasted when one or more of the dies extends beyond a perimeter of the wafer, but there is still a possibility of yielding at least one of the dies from those exposure fields.

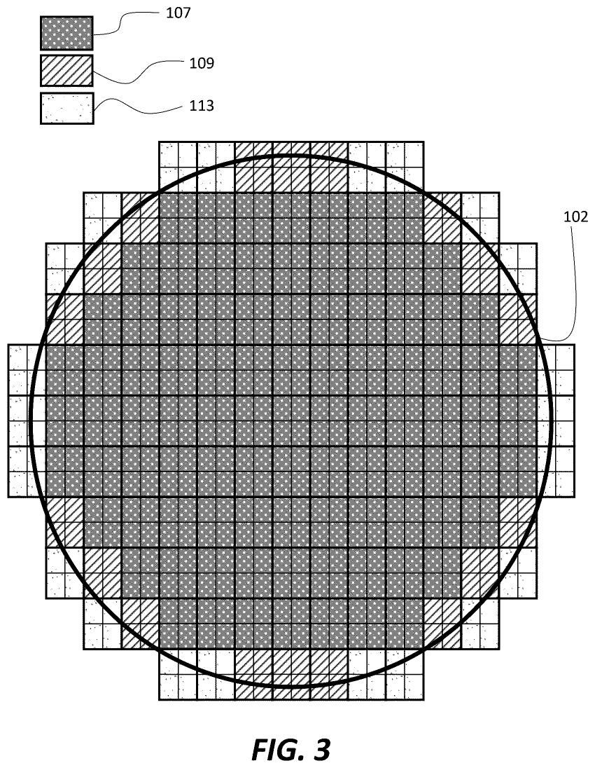

FIG. 3 shows the same layout of FIGS. 1 and 2, but with added exposure fields 113 with its corresponding hatch pattern. These designate edge fields that have no dies that fall within the wafer perimeter. These edge fields are exposures that will not print any complete integrated circuit pattern. Accordingly, from the perspective of scanner time and cost (especially an EUV scanner), executing exposures in these fields is costly and undesirable, but if these edge fields are not exposed and patterned then adjacent dies will suffer from non-uniform etching, causing yield to go down. Thus, all three of these types of fields need to be exposed to increase yield. As can be appreciated, this is an expensive use of high-resolution lithography tools only to provide better etch uniformity of the inner field dies. As an example, printing with EUV in the edge and partial fields can increase processing time by 25%, with this increase in time essentially printing non-working chips. Note that if exposure fields have only one die instead of multiple dies, then all exposure fields 109 and 113 would be nonfunctional.

EUV throughput proportionally depends on a number of fields to be exposed. The need to expose non-working portions of the wafer, accordingly, reduces throughput. Techniques herein include using a separate tool or system or module to expose partial field and/or edge field regions on a wafer to reduce cost, increase throughput and maintain yield. Such techniques can include using a lithography system with lower resolution compared to the primary exposure of working chips, such as compared to an EUV exposure system. As discovered herein, pattern density scale does not need to be in the tens of nanometers (the resolution of EUV tools), but can have a lower resolution, such as a resolution on the order of 100 microns, and still provide a matching feature density in terms of equivalent plasma processing response. Plasma sheath heights are typically a few millimeters. Scribe lanes have different pattern density and do not appear to create problems. By way of a non-limiting example, a 20-micron image resolution pattern is sufficient to provide a matching pattern density of an EUV pattern.

Note that printing a 20-micron image resolution pattern is significantly less costly than printing with EUV tools. And the processing speed of lower resolution photolithography tools is greater than EUV system processing speed. Moreover, multiple lower-resolution photolithography tools can be simultaneously used to increase throughput. The lower-resolution photolithography tools can be a small fraction of the cost and size of an EUV photolithography system. While EUV photolithography systems are among the largest tools in a fab, lower-resolution photolithography systems herein can be embodied as a module within a coater-developer (track) system, especially positioned within an interface region between a scanner and a coater-developer.

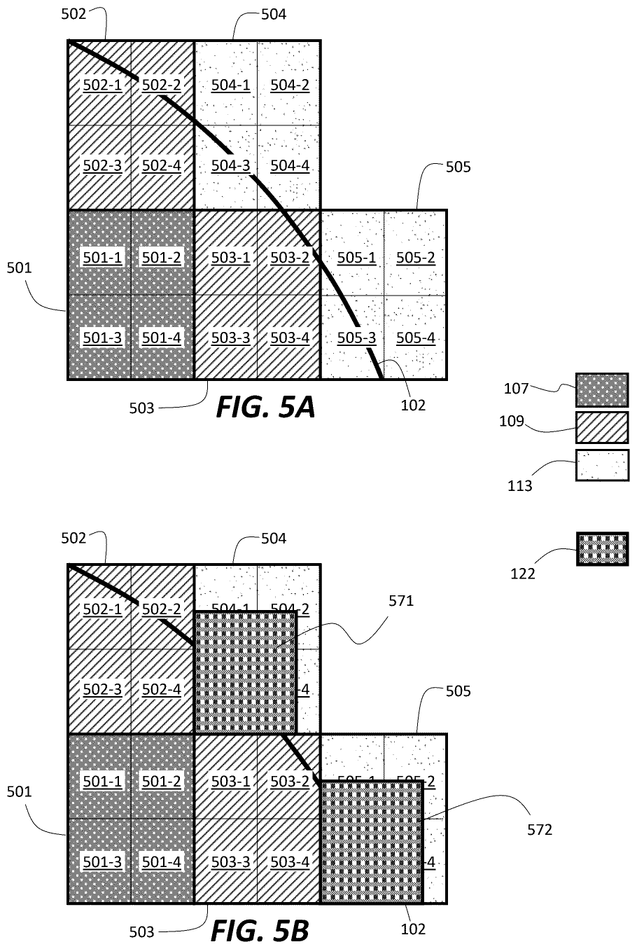

Referring now to FIG. 5A, an enlarged section of a wafer layout is shown. There are five exposure fields (501, 502, 503, 504, and 505) illustrated along a segment of an edge region of wafer 102. Exposure field 501 includes dies 501-1, 501-2, 501-3, and 501-4, all of which are within the perimeter of wafer 102. Exposure field 502 includes dies 502-3 and 502-4 which are fully on the wafer. Dies 502-1 and 502-2, however, extend beyond the edge of the wafer. Likewise, exposure field 503 has a portion of dies on the wafer (three of four). Dies 503-1, 503-3, and 503-4 all fully fit within the wafer surface, while die 503-2 (location for die 503-2) extends beyond the wafer perimeter. This means that exposure fields 502 and 503 should be fully exposed to patterned EUV radiation because of working dies, or potentially working dies, within exposure fields 502 and 503. Exposure fields 504 and 505, in contrast, have none of their dies (dies 504-1, 504-2, 504-3, 504-4, 505-1, 505-2, 505-3, and 505-4) fitting fully on the wafer surface. This means that a patterned EUV exposure within exposure fields 504 and 505 is undesirable as extremely costly compared to its benefit.

Techniques herein provide the benefit of an EUV exposure of exposure fields 504 and 505, but without the cost of an EUV exposure and loss of EUV tool time. FIG. 5B shows secondary exposure fields 571 and 572. Methods herein refrain from patterned EUV exposure of exposure fields 504 and 505, and instead exposure fields 571 and 572 will be exposed using a separate photolithography system that uses a lower-resolution patterning wavelength. Note that an exposure field size of the secondary exposure does not need to be the same size as an EUV exposure field. The secondary exposure field can be smaller or larger than EUV field sizes. Accordingly, a number of secondary exposures can be executed based on field size and remaining wafer surface areas to be exposed. If the secondary exposure field has a smaller field size compared to a particular EUV field, then more individual secondary exposures might need to be executed compared to edge EUV exposures. In the example of FIG. 5B, then secondary exposure fields 571 and 572 happen to be smaller than exposure fields 504 and 505, but they are sufficiently large to cover or expose the remaining wafer portions not receiving an EUV exposure.

Depending on EUV exposure field size, number of dies per exposure field, and size of exposure field, there can be a variation in a number of EUV exposure fields with no functional dies. For example, 10-40 (more or less) exposure field regions, per wafer can have no functional dies. This extra exposure using high-end lithography (EUV), has a significant cost to an operator. With techniques herein, the EUV edge field exposure is replaced with a DUV exposure that results in a matching pattern density in terms of uniform etch performance.

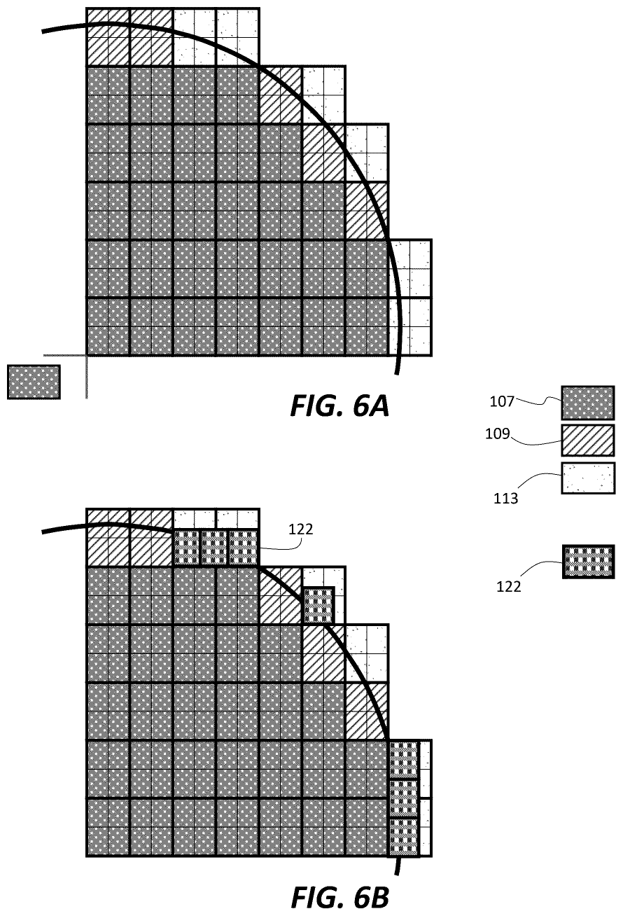

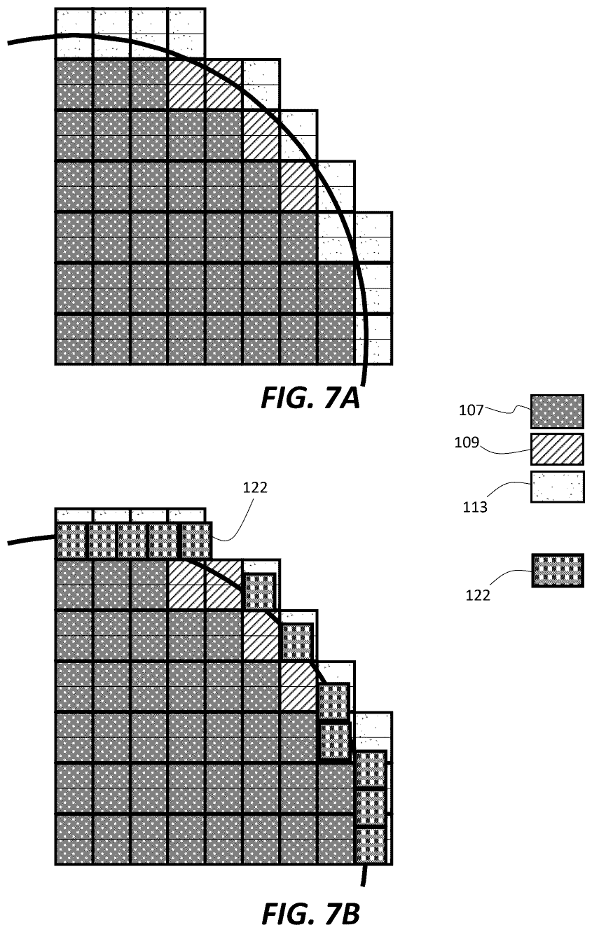

FIGS. 6A and 6B show example layouts with different field sizes on a wafer with a quarter of the wafer shown. FIG. 6A shows an example with a relatively larger field size case of 25×30mm. There are about 24 edge fields needed just for density matching, with about 20 edge fields containing workable dies. FIG. 6B shows that about 21 secondary edge field exposures (122) are needed on the wafer to create a matching pattern density along the wafer edge. Higher throughput EUV typically means a smaller edge field. In FIG. 7A, an example is illustrated with a relatively smaller field size of 20×26 mm. This layout means approximately 40 EUV edge field exposures just for density matching. In some layout designs, lower EUV throughput can mean more edge fields. FIG. 7B shows about 48 secondary edge field exposures (122) can be executed to cover the edge field regions to print a matching pattern density without printing EUV patterns in those regions.

As disclosed herein, various hardware configurations are contemplated herein for an edge die exposure system for secondary exposure of edge regions of a wafer. A pattern of actinic radiation is applied to the edge regions using a lesser resolution lithography system.

In some embodiments, an edge die exposure system (tool) provides proximity printing. For example, a light source for the edge die exposure system can use a wavelength greater than a wavelength of the primary exposure. The cost of photolithography systems as well as their operation costs generally increase with decreasing wavelength. EUV patterned exposure typically uses a wavelength of 13.5 nanometers. The next highest conventional lithography resolutions are dry and immersion scanners using 193 nanometer wavelength light. By way of a non-limiting example, edge die exposure systems herein can operate using 257 nm or 266 nm or other wavelengths. Such DUV systems and other lithography printers can be 300 times less in operation costs compared to an EUV system. Fortunately, these longer wavelengths can also create a solubility shift within EUV chemically-amplified resists (CAR). Note that resist formulation compatibility is needed for proper execution of techniques herein because a given layer of photoresist herein benefits from being photosensitive to two different light wavelengths. Many conventional photoresists have existing formulations with photosensitivity to multiple wavelengths. Metal-containing EUV resists, such as metal-oxide resists, can either be reformulated or include additives to be sensitive to multiple wavelengths. Such resist formulations are within the capability of conventional resist suppliers and inherent in some commercially available photoresists.

Exposure systems herein can also include projection and projection talbot. In some embodiments, a same wavelength exposure can be used for both the working die exposures and the edge die exposures, but with a lower resolution mask or generic mask, or a mask that can support blanket exposure of edge die regions exposure to increase throughput and decrease cost. Preferably, a deep UV tool is used for the edge die exposure.

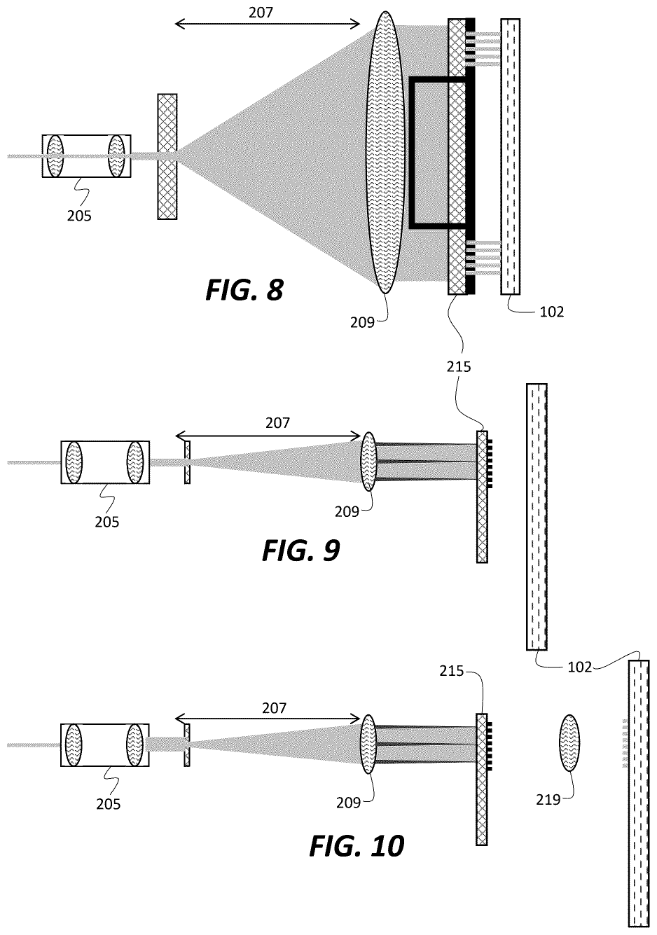

FIGS. 8, 9, and 10 illustrate several example configurations for edge die exposure systems herein. FIG. 8 depicts full wafer proximity printing. FIG. 9 depicts step and repeat projection printing. FIG. 10 depicts step and repeat proximity printing. Other exposure techniques, such as direct-write and blanket exposure can also be used. The examples in FIGS. 8, 9, and 10 have several elements in common and can be described together for shared aspects.

A beam expander 205 can be used to increase a diameter of a laser or exposure beam and increase its collimation over a distance. Optics can then be configured to adjust a convergence angle (207) as the exposure beam reaches condenser lens 209. The condenser lens 209 can gather and focus light from the source to uniformly control its intensity and angle, and to help control resolution and depth of field. Mask 215 can be positioned on a stage or other positioning mechanism. In some configurations, a second condenser lens 219 can optionally be used. The mask 215 patterns the exposure beam so that a pattern of actinic radiation reaches wafer 102. This pattern of actinic radiation then creates a latent pattern in a layer of photoresist at edge die locations. This latent pattern matches or approximates a pattern density of latent patterns formed in the layer of photoresist for active die or integrated circuits fully within the wafer perimeter.

Selection of an edge die exposure system herein can be based on considering advantages and disadvantages of each, relative to design objectives. Full wafer proximity printing can include relatively large optics (condenser lens), large mask handling, and one mask per layer or device is used. This can mean needing many different masks. Such a configuration can have lower throughput being photon limited but can provide a single exposure for the entire wafer.

Using a step and repeat projection printing configuration provides a best resolution, with submicron resolution. There is an efficiency advantage with the light source used, and a single mask can be used for all devices/layers in a given design. Another option is step and repeat proximity printing. This configuration is a low-resolution exposure, on the order of 5 microns depending on the exposure gap. This configuration provides the best photon efficiency with less complex hardware, and a single mask can be used for all devices/layers, providing an economical solution.

An example configuration of systems herein using proximity printing can, for example, use 257/266 nm wavelengths. In this example, a 6-inch mask is used with 20 different pattern densities and 5% steps in pattern density. An exposure gap can be 50-100 microns for less than 10 micron resolution. A dual stage system can optionally be incorporated. A reticle stage can move the reticle to a specific pattern density within the mask. The wafer stage can step around the wafer. A 330×330 mm fast moving stage can also be used. Resolution can be determined as ~k\sqrt{λg}~1.5\sqrt{0.26*50}~5.5 mm. A converging angle determines actual resolution of exposure. Larger angles can be used to reduce speckle problems, but a smaller angle provides better resolution.

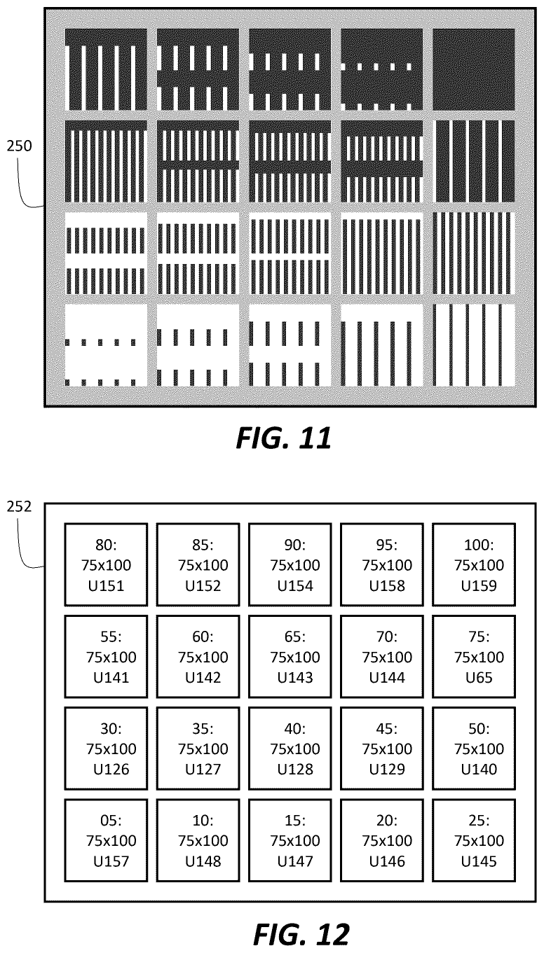

FIG. 11 illustrates an example reticle design herein, while FIG. 12 shows a reticle map corresponding to the reticle design of FIG. 11. This is an illustration of how reticle layout can be executed for efficiency. In this embodiment, a single reticle includes multiple different mask density patterns of incremental differences in pattern density. This particular example has a field size of 15×20 mm, with a density step/change of 5%. In other words, techniques herein include a single reticle having multiple different patterns providing a selection for exposing edge die to match a pattern density to a corresponding EUV pattern for cost and time savings. Note that die patterns in this reticle are not necessarily functioning die patterns, but any geometric pattern that provides a feature density matching a feature density of a corresponding EUV die pattern so that to an etching tool, the relief patterns look the same and thereby provides uniform etching. Pattern density can be determined as the ratio of the patterned area to a total area within a defined region, such as an exposure field.

In other words, a wafer has EUV patterns exposed and developed on inner dies to become functioning integrated circuits, and then for the dies that are not fully on the wafer, a pattern of similar density is printed thereon, using a less costly exposure system. This results in a developed wafer having an etch mask with uniform density across the surface of the wafer, but created more efficiently and at lower cost, to maximize etch efficiency while minimizing cost. FIG. 11 shows a visual representation of different mask densities, while FIG. 12 shows individual mask numbering and density value. With such a reticle of many pattern densities, a same reticle can be used with multiple different EUV patterns. A pattern density of a given EUV pattern is determined, then an edge die exposure mask from the reticle is selected that best matches the given EUV pattern. This selected mask is then moved around by a stage to be used to pattern actinic radiation to exposure edge die regions.

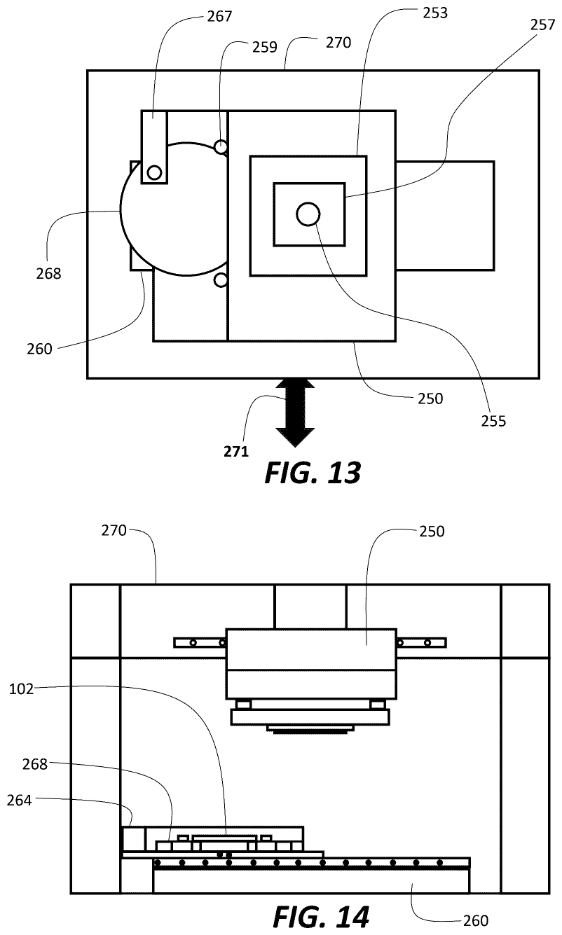

FIGS. 13 and 14 illustrate an example embodiment of an edge die exposure module 270 that can be positioned with a coater-developer system (track tool). Having the edge die exposure system in a coater-developer tool means that the secondary exposure or edge die exposure herein can be executed immediately prior to or subsequent to an EUV exposure or other high-end exposure of the working dies.

FIG. 13 shows a top view of the edge die exposure module 270, while FIG. 14 shows a side view of the edge die exposure module 270. Robot access 271 is used for inserting and removing a wafer 102 from the module. Wafer 102 is placed on wafer chuck 268. Wafer chuck 268 can then secure the wafer 102 in place. Wafer stage 264 is positioned on base 260. Base 260 can be a granite base or other base providing stability to handle movement. Wafer stage 264 is configured to move on base 260 in at least two directions (X, Y), and can optionally include vertical movement (Z) to assist with focusing.

Exposure system 250 is positioned at the upper region of edge die exposure module 270. Exposure system 250 can also be configured for movement in horizontal and vertical directions. Thus, the wafer stage 264 and/or the exposure system 250 can be moved for alignment, focusing and exposure. Exposure laser 255 and accompanying optics can be stationary or move at the upper region of the edge die exposure module 270. Reticle 257 can be moved independently of the exposure laser 255 and optics so that a particular mask with desired pattern density can be selected for edge exposure. Upper reticle stage 253 can be used for reticle movement. Additional sensors and devices can be used to assist with alignment and exposure such as alignment camera 259 as well as wafer height sensor 267. As can be appreciated, modifications can be made for a particular optical system selected for use as well as, size, footprint, and other variables.

Regarding light sources, there are conventionally available light sources or lasers providing 257/266 nm light, of various wattages, wavelengths, pulse durations, and lifetime duration. Note also that any light exposure system can be used herein for the edge exposure. For example, projection exposure, proximity exposure, direct-write, blanket exposure, and other techniques. Techniques herein can also be used for 193 nm scanners and steppers to expose edge regions with a less costly lithography exposure. The edge die exposures herein are density matched to a circuit pattern of interest. This means that the edge die exposures can have a resolution significantly less than the circuit pattern of interest.

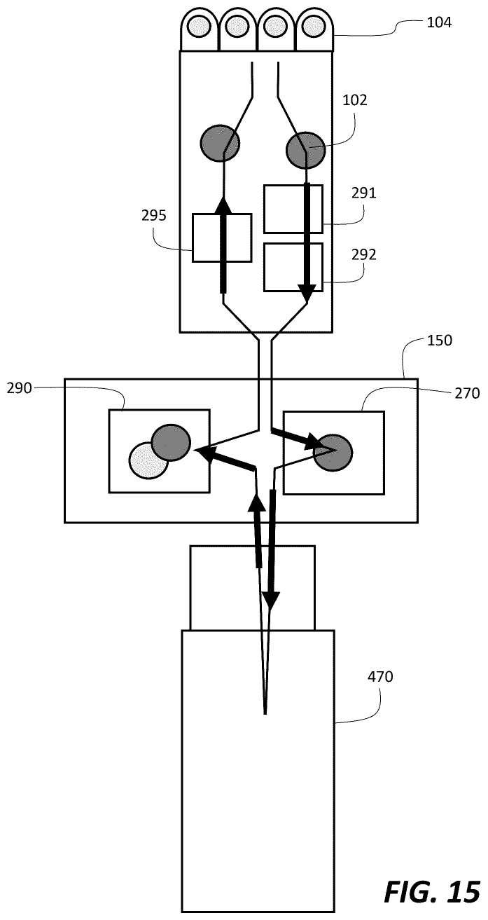

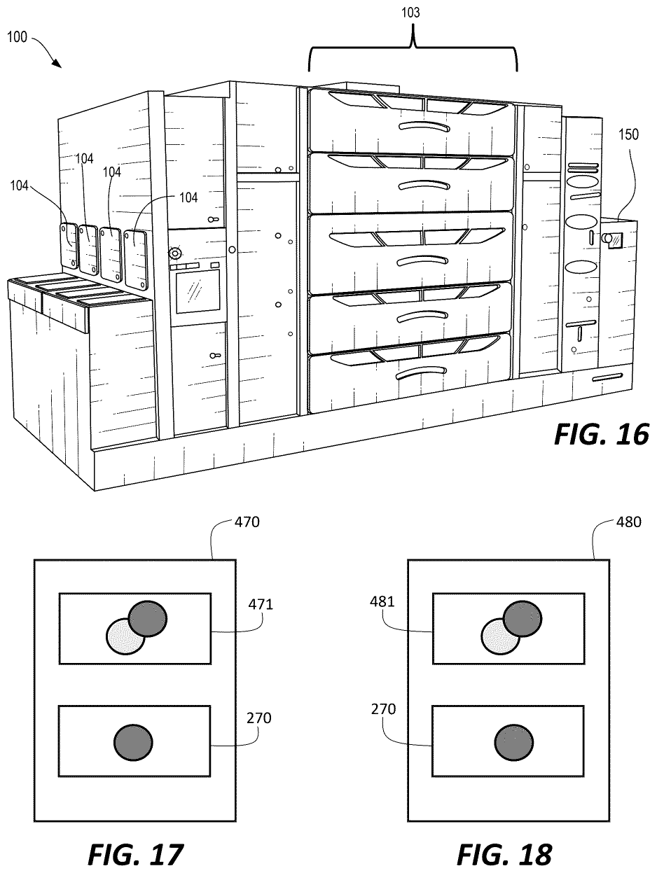

FIG. 15 shows a simplified schematic configuration of an edge die exposure system 150 connected to, or part of, one end of a coater-developer tool 100, shown in FIG. 16. From the perspective view of coater-developer tool 100, at the opposite end there are wafer load ports 104 for loading and removing wafers from the system. The center section 103 contains multiple modules including coating modules 291, baking modules 292, and development modules 295.

The edge die exposure system 150 can include both the edge die exposure module 270 and a whole wafer CD exposure module 290 that is a location-based augmentation exposure tool to improve across-waver CD uniformity. The coater-developer tool 100 can then be a standalone tool or be connected to a scanner 470. The coater-developer tool 100 includes wafer transport robotics configured to move wafers from wafer load ports 104 through the coater-developer system to receive a layer of photoresist deposited thereon, then moved to a bake module to bake the layer of photoresist in preparation for exposure. The robotic system can then move wafers to edge die exposure system 150. A CD augmentation exposure can be executed before or after scanner exposure. The CD augmentation exposure can add about 1-5% additional actinic radiation at location specific regions to improve CD uniformity. Likewise, an edge die exposure can be executed before or after scanner exposure.

The robotic system can then move wafers to scanner 470 for patterned exposure to create various integrated circuit components. Preferably, scanner 470 is an EUV exposure system. The EUV exposure system is then used to expose fields that are fully within a wafer perimeter or that have one or more dies fully within the wafer perimeter. The EUV exposure system is not used (does not need to be used) to expose fields or dies that are partially on the wafer or that have no dies fully on the wafer. Then the edge die exposure system can pattern exposure fields on the wafer not having received any EUV patterned exposure (primary patterning exposure or circuit pattern exposure). After primary exposure, edge die exposure, and any CD adjustment exposure, wafers can receive a post-exposure bake to set latent patterns prior to development. After development, the wafer can be moved to an etching system to use the photoresist relief pattern as an etch mask in a plasma etching tool. With techniques herein, etch results will be maintained while benefiting from a lesser cost for the primary patterning exposure. With both usable dies and partial die areas having a similar density relief pattern, a plasma etch process can be executed with high uniformity maintained.

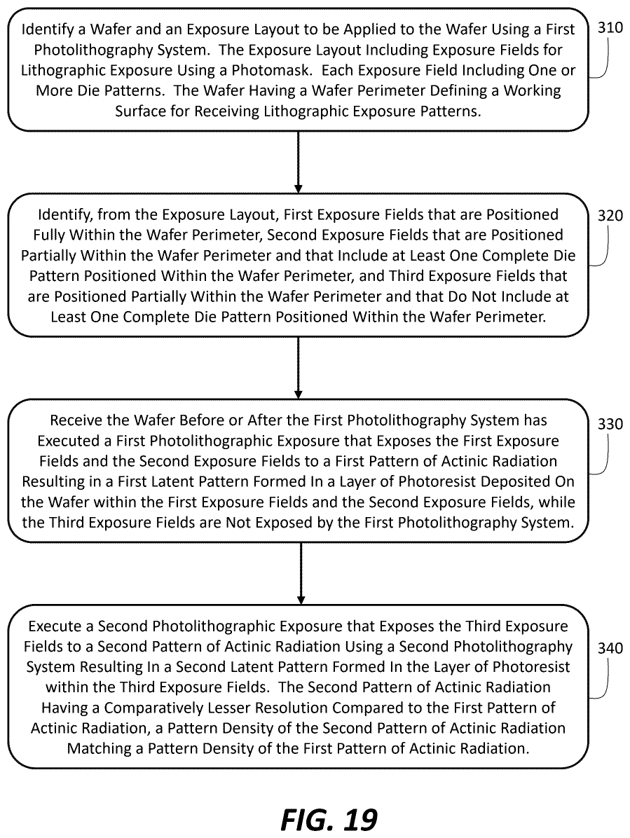

Example embodiments herein can include methods of processing a wafer. Referring now to FIG. 19, in step 310 a wafer is identified as well as an exposure layout to be applied to the wafer using a first photolithography system. The exposure layout includes exposure fields for lithographic exposure using a photomask. Each exposure field includes one or more die patterns. An exposure field with one die pattern can include a component or portion of one die pattern. An exposure field with only a portion/component of a die pattern will typically have this partial die pattern occupying the entire exposure field. The wafer has a wafer perimeter defining a working surface for receiving lithographic exposure patterns.

In step 320, the method includes identifying, from the exposure layout, first exposure fields that are positioned fully within the wafer perimeter. Also identified are second exposure fields that are positioned partially within the wafer perimeter and that include at least one complete die pattern (or defined component thereof) positioned within the wafer perimeter. Also identified are third exposure fields that are positioned partially within the wafer perimeter and that do not include at least one complete die pattern positioned within the wafer perimeter, or complete component thereof that can be stitched to a corresponding die. Alternatively, the method includes identifying a first group of exposure fields including at least one complete die pattern positioned within the wafer perimeter, and then identifying a second group of exposure fields that do not contain at least one complete die pattern positioned within the wafer perimeter.

In step 330, the wafer is received before or after the first photolithography system has executed a first photolithographic exposure that exposes the first exposure fields and the second exposure fields to a first pattern of actinic radiation resulting in a first latent pattern formed in a layer of photoresist deposited on the wafer within the first exposure fields and the second exposure fields, while the third exposure fields are not exposed by the first photolithography system.

In step 340, the method executes a second photolithographic exposure that exposes the third exposure fields to a second pattern of actinic radiation using a second photolithography system resulting in a second latent pattern formed in the layer of photoresist within the third exposure fields. The second pattern of actinic radiation has a comparatively lesser resolution compared to the first pattern of actinic radiation. A pattern density of the second pattern of actinic radiation matches a pattern density of the first pattern of actinic radiation. This matching of pattern density can be within a predetermined tolerance, such as a percentage difference based on a density value or quantification.

The first photolithography system can be an extreme ultraviolet lithography system that generates the first pattern of actinic radiation at a first wavelength between 10 nanometers and 100 nanometers. The second photolithography system can be a deep ultraviolet lithography system that generates the second pattern of actinic radiation at a second wavelength between 101 nanometers and 300 nm. The second photolithography system is a direct-write exposure system that executes the second lithographic exposure by generating a geometrical patten that matches the pattern density of the first pattern of actinic radiation within five percent variation in density. Direct-write can be implemented using a scanning laser, laser galvanometer, or digital light projection that projects an entire pattern at one time.

The second photolithography system can alternatively be a mask-based exposure system that uses a reticle having multiple exposure field patterns that vary in pattern density relative to each other, with any of the multiple exposure field patterns available for use with the second photolithographic exposure.

Executing the second photolithographic exposure can include identifying a first pattern density value of the first pattern of actinic radiation, identifying a matching exposure field on the reticle having a second pattern density value closest to the first pattern density value, and then using the matching exposure field for executing the second photolithographic exposure. The second photolithographic exposure is executed within a module positioned within a coater-developer system.

The layer of photoresist is selected to be sensitive to two different wavelengths in that the two different wavelengths cause a solubility shift in the layer of photoresist. Methods can include generating a reticle having multiple different lithographic patterns. Each lithographic pattern, on the reticle, has a pattern density value that varies relative to each other resulting in the multiple different lithographic patterns each having a different pattern density value.

The first latent pattern can be simultaneously developed with the second latent pattern resulting in the layer of photoresist forming a relief pattern. Then, a first etch process can be executed that transfers the relief pattern into one or more underlying layers.

In another method of processing a wafer, steps include identifying a wafer and an exposure layout to be applied to the wafer using a first photolithography system. The exposure layout includes exposure fields for lithographic exposure using a photomask. Each exposure field includes one or more die patterns (or one die pattern component to be stitched or combined with another). The wafer has a wafer perimeter defining a working surface for receiving lithographic exposure patterns. A further step includes identifying, from the exposure layout, first dies that are positioned fully within the wafer perimeter and second dies that are positioned partially within the wafer perimeter.

The wafer is received before or after the first photolithography system has executed a first photolithographic exposure that exposes the first dies to a first pattern of actinic radiation resulting in a first latent pattern formed in a layer of photoresist deposited on the wafer within the first dies (first die locations), while the second dies (second die locations) were not exposed by the first photolithography system. And then a second photolithographic exposure is executed that exposes at least a portion of the second dies (second die locations) to a second pattern of actinic radiation using a second photolithography system resulting in a second latent pattern formed in the layer of photoresist within the portion of second dies or second die locations. The second pattern of actinic radiation has a different geometrical pattern compared to the first pattern of actinic radiation. The second pattern of actinic radiation matches a pattern density of the first pattern of actinic radiation within a predetermined value of variation or deviation.

In some embodiments, the predetermined value of variation is a variation of up to ten percent variation between exposed patterns. This could also be 20 percent or 30 percent or more while still receiving a benefit to etch uniformity. Minimizing variation, however, increases etch uniformity. The first photolithography system is an extreme ultraviolet lithography system that generates the first pattern of actinic radiation at a first wavelength between 10 nanometers and 100 nanometers, while the second photolithography system is an ultraviolet lithography system that generates the second pattern of actinic radiation at a second wavelength between 101 nanometers and 300 nm.

Another embodiment can include a coater-developer system for processing a semiconductor wafer. The coater-developer system includes an equipment front-end module having a mechanism for loading and unloading one or more wafers to be processed. A wafer processing region having multiple wafer processing modules including modules configured for coating wafers via spin-on deposition, modules configured for baking wafers, and modules configured for developing exposed wafers. A tool interface module defines a region to physically connect the coater-developer tool to a photolithographic exposure tool for exposure of circuit patterns using EUV lithography. The tool interface module is configured to collect and store a queue of wafers for transfer to, and reception from, the photolithographic exposure tool.

Another embodiment includes a scanner system for processing a semiconductor wafer. FIG. 17 illustrates a schematic layout of scanner 470. This scanner 470 can include exposure optics 471, which are designed for creating a pattern on a layer of photoresist. Edge die exposure module 270 can be included in this scanner. In other words, the edge die exposure module can be positioned within a scanner/stepper tool, such as an EUV tool, for edge die exposure right before or right after primary exposure. Edge die exposure module 270 takes up comparatively little room so would fit within conventional scanners.

Another embodiment includes a dry develop system for processing a semiconductor wafer. FIG. 18 illustrates a schematic layout of dry developer system 480. Dry development refers to plasma-based or gas-based or vapor-phase development of patterned layers of photoresist. These layers of photoresist can be deposited by spin-on deposition or vapor-phase deposition. Such system typically include one or more chambers for dry development, such as chamber 481. Techniques herein include edge die exposure module 270 positioned within the dry developer system 480. Not that edge die exposure module 270 can also be positioned within other semiconductor tools found within a fab.

The system includes a robotic wafer transport system configured to move wafers from the equipment front-end module to wafer processing regions, configured to move wafers among wafer processing modules in the wafer process regions, and configured to move wafers from the wafer processing regions to the tool interface module.

An edge die exposure module is positioned within the tool interface module, the edge die exposure module includes a UV or DUV exposure system having optics and a pattern generation mechanism to expose edge die regions with a pattern of actinic radiation that has a pattern density matching a pattern density of an EUV pattern of radiation corresponding to dies fully on a working surface of the wafer, the edge die regions including dies that are partially on the working surface of the wafer and extend beyond a wafer perimeter.

The edge die exposure module can use an exposure mechanism selected from the group consisting of direct-write printing, full wafer proximity printing, proximity printing with step and repeat exposure, and projection printing with step and repeat exposure. The coater-developer system can further include a critical dimension exposure module positioned within the tool interface module. The critical dimension exposure module includes a direct-write lithographic exposure system configured to add additional actinic radiation to a layer of photoresist on the wafer using location-specific adjustment of actinic radiation intensity. The additional actinic radiation added at each point location being less than 5% of a corresponding patterning dose from photolithographic exposure systems.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method of processing a wafer, the method comprising:
identifying a wafer and an exposure layout to be applied to the wafer using a first photolithography system, the exposure layout including exposure fields for lithographic exposure using a photomask, each exposure field including one or more die patterns, the wafer having a wafer perimeter defining a working surface for receiving lithographic exposure patterns;
identifying, from the exposure layout, first exposure fields that are positioned fully within the wafer perimeter, second exposure fields that are positioned partially within the wafer perimeter and that include at least one complete die pattern positioned within the wafer perimeter, and third exposure fields that are positioned partially within the wafer perimeter and that do not include at least one complete die pattern positioned within the wafer perimeter;
receiving the wafer before or after the first photolithography system has executed a first photolithographic exposure that exposes the first exposure fields and the second exposure fields to a first pattern of actinic radiation resulting in a first latent pattern formed in a layer of photoresist deposited on the wafer within the first exposure fields and the second exposure fields, while the third exposure fields are not being exposed by the first photolithography system; and
executing a second photolithographic exposure that exposes the third exposure fields to a second pattern of actinic radiation using a second photolithography system resulting in a second latent pattern formed in the layer of photoresist within the third exposure fields, the second pattern of actinic radiation having a comparatively lesser resolution compared to the first pattern of actinic radiation, a pattern density of the second pattern of actinic radiation matching a pattern density of the first pattern of actinic radiation.

2. The method of claim 1, wherein the first photolithography system is an extreme ultraviolet lithography system that generates the first pattern of actinic radiation at a first wavelength between 10 nanometers and 100 nanometers.

3. The method of claim 2, wherein the second photolithography system is a deep ultraviolet lithography system that generates the second pattern of actinic radiation at a second wavelength between 101 nanometers and 300 nm.

4. The method of claim 1, wherein the second photolithography system is a direct-write exposure system that executes the second lithographic exposure by generating a geometrical patten that matches the pattern density of the first pattern of actinic radiation within five percent variation in density.

5. The method of claim 1, wherein the second photolithography system is a mask-based exposure system that uses a reticle having multiple exposure field patterns that vary in pattern density relative to each other, with any of the multiple exposure field patterns available for use with the second photolithographic exposure.

6. The method of claim 5, wherein executing the second photolithographic exposure includes:
identifying a first pattern density value of the first pattern of actinic radiation;
identifying a matching exposure field on the reticle having a second pattern density value closest to the first pattern density value; and
using the matching exposure field for executing the second photolithographic exposure.

7. The method of claim 1, further comprising:
simultaneously developing the first latent pattern and the second latent pattern resulting in the layer of photoresist forming a relief pattern.

8. The method of claim 7, further comprising:
executing a first etch process that transfers the relief pattern into one or more underlying layers.

9. The method of claim 1, wherein the layer of photoresist is selected to be sensitive to two different wavelengths in that the two different wavelengths cause a solubility shift in the layer of photoresist.

10. The method of claim 1, wherein the second photolithographic exposure is executed within a module positioned within a coater-developer system.

11. The method of claim 1, further comprising:
generating a reticle having multiple different lithographic patterns, each lithographic pattern having a pattern density value that varies relative to each other resulting in the multiple different lithographic patterns each having a different pattern density value.

12. A method of processing a wafer, the method comprising:
identifying a wafer and an exposure layout to be applied to the wafer using a first photolithography system, the exposure layout including exposure fields for lithographic exposure using a photomask, each exposure field including one or more die patterns, the wafer having a wafer perimeter defining a working surface for receiving lithographic exposure patterns;
identifying, from the exposure layout, first die locations that are positioned fully within the wafer perimeter and second die locations that are not positioned fully within the wafer perimeter;
receiving the wafer before or after the first photolithography system has executed a first photolithographic exposure that exposes the first die locations to a first pattern of actinic radiation resulting in a first latent pattern formed in a layer of photoresist deposited on the wafer within the first die locations, while the second die locations were not exposed by the first photolithography system; and
executing a second photolithographic exposure that exposes at least a portion of the second die locations to a second pattern of actinic radiation using a second photolithography system resulting in a second latent pattern formed in the layer of photoresist within the at least portion of second die locations, the second pattern of actinic radiation having a different geometrical pattern compared to the first pattern of actinic radiation, while the second pattern of actinic radiation matches a pattern density of the first pattern of actinic radiation within a predetermined value of variation.

13. The method of claim 12, wherein the predetermined value of variation is a variation of up to ten percent variation between exposed patterns.

14. The method of claim 12, wherein the first photolithography system is an extreme ultraviolet lithography system that generates the first pattern of actinic radiation at a first wavelength between 10 nanometers and 100 nanometers.

15. The method of claim 14, wherein the second photolithography system is an ultraviolet lithography system that generates the second pattern of actinic radiation at a second wavelength between 101 nanometers and 300 nm.

16. The method of claim 12, wherein the second photolithography system is a mask-based exposure system that uses a reticle having multiple exposure field patterns that vary in pattern density relative to each other, with any of the multiple exposure field patterns available for use with the second photolithographic exposure.

17. The method of claim 16, wherein executing the second photolithographic exposure includes:
identifying a first pattern density value of the first pattern of actinic radiation;
identifying a matching exposure field on the reticle having a second pattern density value closest to the first pattern density value; and
using the matching exposure field for executing the second photolithographic exposure.

18. A coater-developer system for processing a semiconductor wafer, the coater-developer system comprising:
an equipment front-end module having a mechanism for loading and unloading one or more wafers to be processed;
a wafer processing region having multiple wafer processing modules including modules configured for coating wafers via spin-on deposition, modules configured for baking wafers, and modules configured for developing exposed wafers;
a tool interface module defining a region to physically connect the coater-developer tool to a photolithographic exposure tool for exposure of circuit patterns using EUV lithography, the tool interface module configured to collect and store a queue of wafers for transfer to and reception from the photolithographic exposure tool;
a robotic wafer transport system configured to move wafers from the equipment front-end module to wafer processing region, configured to move wafers among wafer processing modules in the wafer process region, and configured to move wafers from the wafer processing region to the tool interface module; and
an edge die exposure module positioned within the tool interface module, the edge die exposure module including a DUV exposure system having optics and a pattern generation mechanism to expose edge die regions with a pattern of actinic radiation that has a pattern density matching a pattern density of an EUV pattern of radiation corresponding to die locations fully on a working surface of the wafer, the edge die regions including die locations that are partially on the working surface of the wafer and extend beyond a wafer perimeter.

19. The coater-developer system of claim 18, wherein the edge die exposure module uses an exposure mechanism selected from the group consisting of direct-write printing, full wafer proximity printing, proximity printing with step and repeat exposure, and projection printing with step and repeat exposure.

20. The coater-developer system of claim 18, further comprising:
a critical dimension exposure module positioned within the tool interface module, the critical dimension exposure module including a direct-write lithographic exposure system configured to add additional actinic radiation to a layer of photoresist on the wafer using location-specific adjustment of actinic radiation intensity, the additional actinic radiation added at each point location being less than 5% of a corresponding patterning dose from photolithographic exposure systems.
